(19) United States
(12) Patent Application Publication
(10) Pub. No.: US 2011/0164383 A1
(43) Pub. Date: Jul. 7, 2011

(54) DEVICE PROVIDED WITH A GAP-LIKE SPACE AND A SYNTHETIC JET GENERATOR COUPLED THERE-TO

(75) Inventors: Simon Eme Kadijk, Veldhoven (NL); Gwendolyn Anita Luiten, Riethoven (NL); Celine Catherine Sarah Nicole, Eindhoven (NL); Clemens Johannes Maria Lasance, Nuenen (NL)

(73) Assignee: KONINKLIJKE PHILIPS ELECTRONICS N.V, EINDHOVEN (NL)

(21) Appl. No.: 13/062,833

(22) PCT Filed: Sep. 7, 2009
(86) PCT No.: PCT/IB2009/053888

§ 371 Date: Mar. 8, 2011

(30) Foreign Application Priority Data
Sep. 12, 2008 (EP) 08164205.0

(51) Int. Cl. H05K 7/20; F28D 15/00

(52) U.S. Cl. 361/690; 165/104.34

(57) ABSTRACT

A device (1) is provided with a configuration of two walls (3a; 5a) confining a substantially closed gap-like space (7) containing a gaseous medium. For cooling purposes the device is further provided with a synthetic jet generator (9) for generating a gaseous synthetic jet, wherein the generator is fluidically coupled to the gas-like space.

### FIELD OF THE INVENTION

The invention relates to a device provided with a configuration of two walls confining a substantially closed gap-like space extending between said walls and containing a gaseous medium.

### BACKGROUND OF THE INVENTION

In recent years several kinds of large-area devices have been developed. Examples are e.g. thin, flat liquid crystal and plasma display devices. Next generations of such devices are going to be very thin. For instance televisions with a total thickness of 12 mm are aimed at. Moreover new-developed electronic devices for use in large-area displays are more compact and/or more powerful than conventional ones. Usually, designers have strict rules for placing ventilation openings in large-area devices. For all these reasons a need for an improved cooling technology has increased in the field of thin and flat large-area display devices.

### SUMMARY OF THE INVENTION

It is an object of the invention to provide a device of the kind described in the opening paragraph, which is provided with an adequate cooling means for creating a uniform heat spreading over said configuration of the device.

This object is achieved by the features applied into the device according to the invention as defined in claim 1. Particularly, the device according to the invention is provided with a configuration of two walls confining a substantially closed gap-like space extending between said walls and containing a gaseous medium and is moreover provided with a synthetic jet generator for generating a gaseous synthetic jet, wherein the generator is fluidically coupled to the gas-like space. Usually, such a device is provided with one or more heat producing sources, such as heat generating components, e.g. electronic components or light sources.

The invention efficiently solves the problem of thermal management of a device provided with a configuration of two walls confining a substantially closed gap-like space extending there between. In such a configuration the walls are arranged at a gap-distance, i.e. at a small distance from each other. Such a configuration is particularly used in new generations of large-area devices, such as large-screen display apparatus and large-screen luminaires. Usually, such a device has a display panel forming one of said walls and a transparent or translucent front plate, usually a glass plate, forming the other of said walls, wherein the gap-like space extends between the display panel and the front plate. During use, the display panels of such devices can produce an considerable amount of heat, which heat must be transferred to the environment in order to prevent overheating of materials and/or components applied into the devices. The distance between a display panel and the font plate, thus the thickness of the space, is very small, and can be in the order of 2 to 3 mm. It has appeared that conventional technologies are inadequate to create an efficiently cooling air flow in such a narrow space. An additional problem is that the front plate has a degrading effect on the heat transfer coefficient to the surrounding air areas. Experimentally, it is proved that a synthetic jet generator which is fluidically coupled to a substantially closed, including fully closed, gap-like space extending between two large-area walls and having a thickness of 2 to 3 mm is able to create circulations, including re-circulations, of a gaseous medium, particularly air, within the gap-like space. It is further proved that mild circulations of the gaseous medium are already sufficient to create a considerably uniform heat spreading over a large area. Stronger circulations provide a further increased cooling effect.

It is noted that a synthetic jet as well as devices for generating synthetic jets are known per se. A synthetic jet is a flow having a zero net mass flux. Such a flow is alternately pushed in and out, in other words oscillates. An application of a synthetic jet actuator in a cooling apparatus is disclosed in the patent application WO 2005/008348. The synthetic jet actuator is provided with an orifice to which a fixed end of a tube is secured. A free end of the tube forms a tubing exit end. During operation vortices are formed at the edges of the free end, which vortices roll up and move away from the exit end, wherein the generated jet streams are directed across a heated surface.

In a preferred embodiment of the device according to the invention a coupling channel is provided for fluidically coupling the synthetic jet generator to the gap-like space. The coupling channel may be in the form of a tube, pipe and the like. Such a pipe, tube and the like starts from the synthetic jet generator and ends in the gap-like space. This embodiment provides well-desired design freedom, as the synthetic jet generator can be positioned at distance from the gap-like space, and thus at distance from the configuration, at any available location.

In a practical embodiment of the device according to the invention the two walls form a sealed enclosure defining the gap-like space and provided with an aperture, via which aperture the gas-like space communicates with the synthetic jet generator. In this embodiment a dust free cooling is possible. Apart from said aperture no inlet or outlet is needed.

In a practical embodiment of the device according to the invention at least one of the walls is formed by a panel structure.

In a preferred embodiment of the device according to the invention one of the walls is formed by a display panel structure and the other wall is formed by a transparent or translucent plate structure. Such an embodiment must be cooled during operation because of heat produced in or by the display panel structure. The invention provides the required cooling, wherein distribution and/or re-distribution of heat over the walls plays an essential role.

In a preferred embodiment of the device according to the invention, the display panel structure comprises a panel out of the group constituted by a liquid crystal panel (LCD), a plasma panel, an organic light-emitting diode (OLED) panel and a light-emitting diode (LED) panel. All these panels generate during operation a lot of heat and therefore have to be cooled efficiently. For example a LCD panel is provided with one or more lamps and a polariser and is sealed or not sealed with a glass plate being at a distance of about 2 to 3 mm to the panel. The lamps produce an amount of heat during use, which heat must be transferred to the environment without negatively affecting the polariser which is susceptible to temperature related performance and degradation. In the device according to the invention this removal of heat efficiently occurs by creating circulations and re-circulations of the gaseous medium, particularly air, in the narrow space between the panel and the glass plate.

In a practical embodiment of the device according to the invention the transparent or translucent plate structure comprises a glass plate.

In a practical embodiment of the device according to the invention the gaseous medium is air and the gaseous synthetic jet is an air jet.

In a preferred embodiment of the device according to the invention the synthetic jet generator is configured for generating pulses at a frequency being in a range between 0 and 80 Hz, but preferably in the range of 15-50 Hz, which is substantially determined by the dimensions of the coupling channel and the generator. This frequency range provides a zero or low sound level so as to enable a silent behavior. This matter is further discussed in Applicant's patent application with European filing number 07122620.3 (Applicant's reference PH008973); this patent application is hereby incorporated by reference.

In a preferred embodiment of the device according to the invention the synthetic jet generator is formed by a loudspeaker. In using the resonant frequency of the loudspeaker a high efficiency is achievable, whereby an additional cooling of the configuration is achieved while less energy is consumed. Suitable electrodynamic loudspeakers are e.g. disclosed in Applicant's patent applications with European filing number 07110265.1 (Applicant's reference PH008152) and 07122620.3 (Applicant's reference PH008973); both patent applications are hereby incorporated by reference. Nevertheless other transducers having a membrane adapted to generate pressure waves at a working frequency can alternatively be successfully applied. Under the term “transducer” should be understood a device that is capable of converting an input signal to a corresponding pressure wave output. The input signal may be electric, magnetic or mechanical. Examples of suitable transducers include various types of vibrating structures, such as membranes, pistons, piezoelectric structures and the like.

The invention also relates to a display apparatus provided with the device according to the invention. The display apparatus according to the invention can be a television apparatus, a monitor, a notebook and the like.

The invention also relates to a luminary, also called luminaire, preferably provided with LEDs, that is equipped with the device according to the invention.

With reference to the Claims it is noted that all possible combinations of features mentioned in the Claims are part of the invention.

These and other aspects of the invention are apparent from and will be elucidated with reference to the examples described hereinafter.

### BRIEF DESCRIPTION OF THE DRAWINGS

FIG. 1 schematically shows a measurement embodiment of the device according to the invention;

FIG. 2 schematically shows a velocity measurement arrangement;

FIG. 3 schematically shows a laser sheet visualisation arrangement;

FIG. 4A is a schematic front view of a first practical embodiment of the display apparatus according to the invention;

FIG. 4B is a schematic side view of the first practical embodiment;

FIG. 5A is a schematic front view of a second practical embodiment of the display apparatus according to the invention;

FIG. 5B is a schematic side view of the second practical embodiment;

FIG. 6 is a schematic view of a third practical embodiment of the display apparatus according to the invention; and

FIG. 7 is a schematic view of a practical embodiment of the luminary according to the invention.

### DETAILED DESCRIPTION

It is noted that the disclosed embodiments are schematically depicted. It is further noted that similar features in the several figures are denoted by the same reference signs.

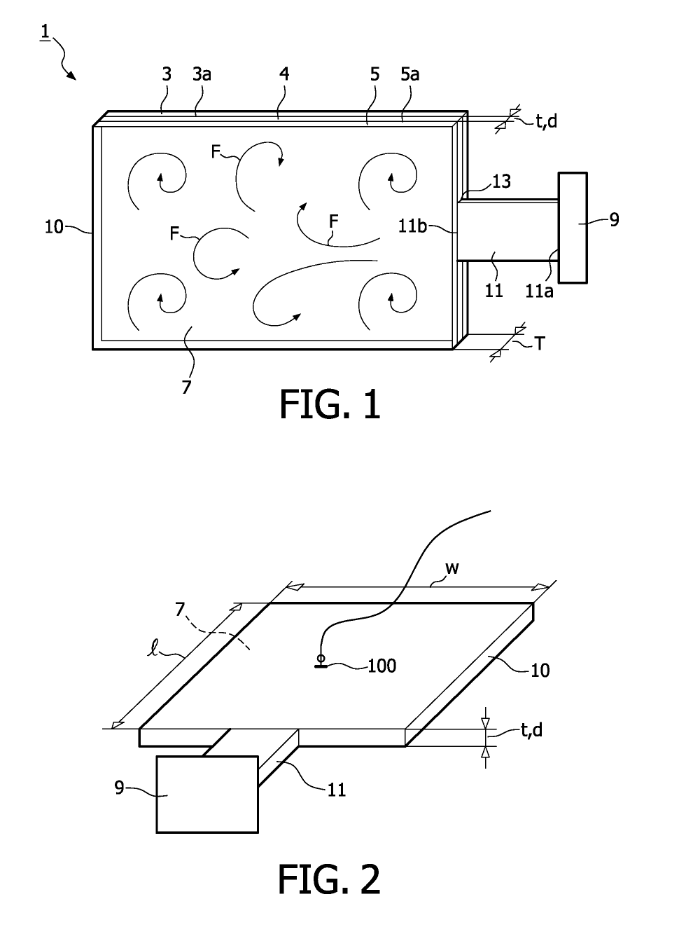

In FIG. 1 a device 1 is depicted, which is provided with a panel or panel structure 3, in this example a LCD display, and a plate or pate structure 5, in this example a transparent glass plate, arranged in front of the panel 3. Alternatively, the panel may be a plasma display or in principle each other suitable kind of panel; the plate 5 may alternatively be a non-transparent plate and may be made in principle from each suitable material. The panel 3 and the plate 5 constitute a configuration of two walls 3a and 5a confining a gap-like space 7 extending between the panel 3 and the plate 5 and closed by a seal 4 at the outline of the structure of panel 3 and plate 5. The gap-like space 7 is filled with a gaseous medium, in this example air. In this embodiment the distance (d) between the parallelly arranged panel 3 and plate 5 is in the order of 2 to 3 mm, whereby the gap-like space 7 has a thickness (t) in the order of 2 to 3 mm. The total thickness (T) of the apparatus 1 is 12 mm. Other thicknesses (t) and (T) are possible.

The device 1 is further provided with a synthetic jet generator 9 for generating a synthetic jet. The synthetic jet generator 9, also called synthetic jet actuator, comprises a transducer for generating pressure waves at a working frequency and is coupled to the gap-like space 7 for providing an output fluid jet, in this example an air jet, having a substantially zero net mass flux. In this example the synthetic jet generator 9 is remotely positioned with regard to the gap-like space 7 and is coupled to the gap-like space 7 by a passage or channel 11 for receiving waves of said pressure waves and for providing said output fluid jet to the gap-like space 7. In this example the passage 11 is a coupling pipe 11. The pipe 11 is connected at one end 11a to the synthetic jet generator 9 and at its other end 11b to the gap-like space 7 via an aperture 13 provided in the seal 4. This aperture is the only opening in the enclosure 10 formed by the panel 3 and the plate 5. The pipe 11 can have a length in a wide range, e.g. between 0 and 200 mm, in this example 120 mm. The pipe has preferably a substantially rectangular cross section with one dimension corresponding to the distance (d). The other dimension is larger, in this example 14 mm. Other cross sections are possible.

As the device 1 is provided with heat generating electronic components, e.g. the LCD panel 3 includes LEDs or lamps, heat is produced during operation. In order to guarantee a long lifetime and good performance, such as lamp efficacy, of the device 1 the display panel 3 must be prevented from overheating. By energizing and adequately controlling the synthetic jet generator 9 a synthetic jet is generated and coupled to the gap-like space 7 via the pipe 11. The obtained effect is a variety of flows (F) in several directions in the gap-like space 7, resulting in is a process of cooling and evenly distributing heat over the panel. Thus an efficient cooling arrangement has been obtained.

In order to demonstrate the obtained effect two kinds of measurements have been performed, viz. a velocity measurement and a flow visualization.

The first kind of measurement includes creating an enclosure 10 having to parallel walls 3a and 5a and forming a gap-like space 7 having a thickness (t) of 3 mm, as depicted in FIG. 2. The enclosure has a length (l) of 500 mm and a width (w) of 170 mm. The narrow space 7 is sealed and filled with air under atmospheric pressure. A synthetic jet generator 9, constituted by a loudspeaker, is coupled the gap-like space 7, using a pipe 11 having a rectangular-shaped cross section of 2 mm by 14 mm and having a length of 120 mm. An anemometer 100 based on a small thermistor is placed in the gap-like space 7 in order to measure the local velocity of the air in the gap-like space 7. During measuring, the anemometer 100 measures the air velocity in all directions at the same time at a rate of 10 Hz. On average the velocity is 1.4 m/s when the loudspeaker operates at 50 Hz. The velocity has been measured at different points in the enclosure 10. The velocity is somewhat higher closer to the pipe 11. Farther away from the pipe 11 the flow is fully multidirectional and therefore techniques to measure reliably the local velocity—Laser Doppler anemometer (LDA) and particle image velocimetry (PIV)—have been applied. In order to assess if there is any flow farther from the synthetic jet or in the corners of the enclosure, these measurements were combined with the above-mentioned kind of measurement, viz. flow visualization.

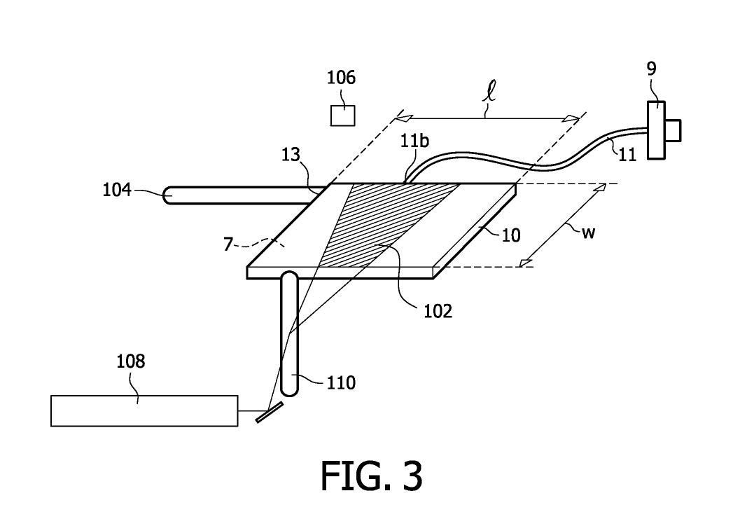

For visualisation, a laser sheet visualisation (LSV) technique was applied, using smoke, supplied via an incense stick 104, as seeding particles, as depicted in FIG. 3. This technique is a qualitative measurement and appropriate as a proof of principle. Combined with a high speed digital camera 106, scanning mirrors (not shown) and appropriate software the measurement results in a quantitative 3D measurement similar to PIV.

An enclosure 10 with a length (l) of 245 mm and a width (w) of 170 mm defines a gap-like space 7. The incense stick 104 was introduced directly in the enclosure 10 through an aperture 13. Used was made of a synthetic jet generator 9 in the form of a loudspeaker, wherein the loudspeaker was fluidically coupled to the enclosure 10 by a pipe 11 having a length of 1 m and a round nozzle 11b. A He—Ne laser 108 of 10 mW, together with a cylindrical lens 110 having a diameter of 14 mm, was used to create a laser sheet 102. The digital camera 106 was positioned above the enclosure 10 to make short movies and to take pictures. During use of the synthetic jet generator at optimum frequencies it is very difficult to observe flows by eye and with a low speed camera. Only the disappearance of the laser speckle effect due to the frequency induced on the air in the enclosure could be observed. Operating the synthetic jet generator 9 at a lower frequency (2 Hz, 1 W) and seeding more smoke, the air (and smoke) circulating in the closed enclosure was clearly perceptible. More particularly, circulations in the whole gap-like space 7 were clearly visible, even circulations in the corners in all directions. Such circulations are schematically shown in FIG. 1 by the letter F. When the synthetic jet generator 9 was turned off, the air (and smoke) was standing still without any velocity component.

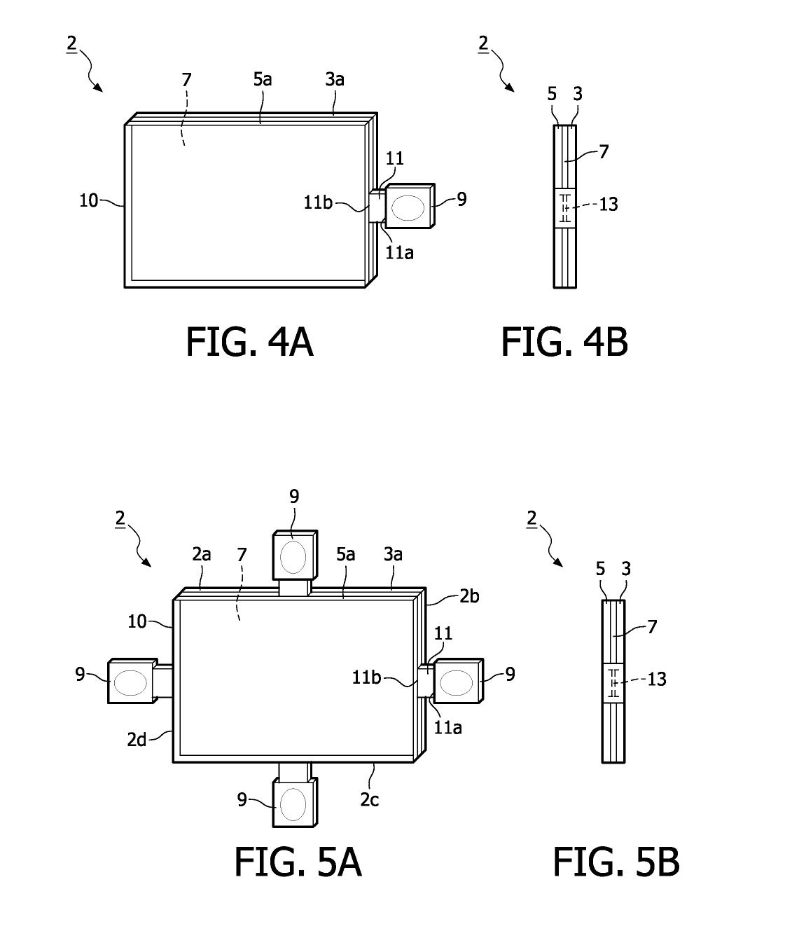

In FIGS. 4A and 4B a display apparatus 2 is disclosed, provided with a configuration of two walls 3a and 3b confining a substantially closed gap-like space 7 extending there between and containing air. The display apparatus 2 is further provided with a synthetic jet generator 9, formed by a loudspeaker, for generating a synthetic jet. The generator 9 is fluidically coupled to the gas-like space 7 by means of a tube 11 with a slit-like rectangular cross section. The wall 3a is constituted by a LCD panel structure 3, while the wall 5a is formed by a plate 5 of transparent glass arranged in front of the LCD panel structure. The panel structure 3 and the plate 5 together form a sealed enclosure 10 enclosing the gap-like space 7 and being provided with an aperture 13 to which one end 11b of the tube 11 is connected. The other end 11a of the tube 11 is connected to the synthetic jet generator 9. By this construction the synthetic jet generator is able communicate with the gas-like space 7 via the tube 11 and the aperture 13, in a way as already described in the foregoing. In this example the display apparatus 2 is a large-area LCD television. Alternatively the apparatus may be a display monitor, a closed space containing lamps in a backlight unit of a display with lamps, for example a cold cathode fluorescent lamp (CCFL) display, a closed space at the rear of a display panel, for example a space containing a circuit board, or similar structures.

In FIGS. 5A and 5B a display apparatus 2 is disclosed, which mainly distinguishes itself from the apparatus disclosed in FIGS. 4A and 4B by the provision of four synthetic jet generators 9, four tubes 11 and consequently four apertures 13. More particularly, each small side 2a to 2d of the apparatus 2 is provided with an aperture 13. For the rest reference is made to the former described display apparatus.

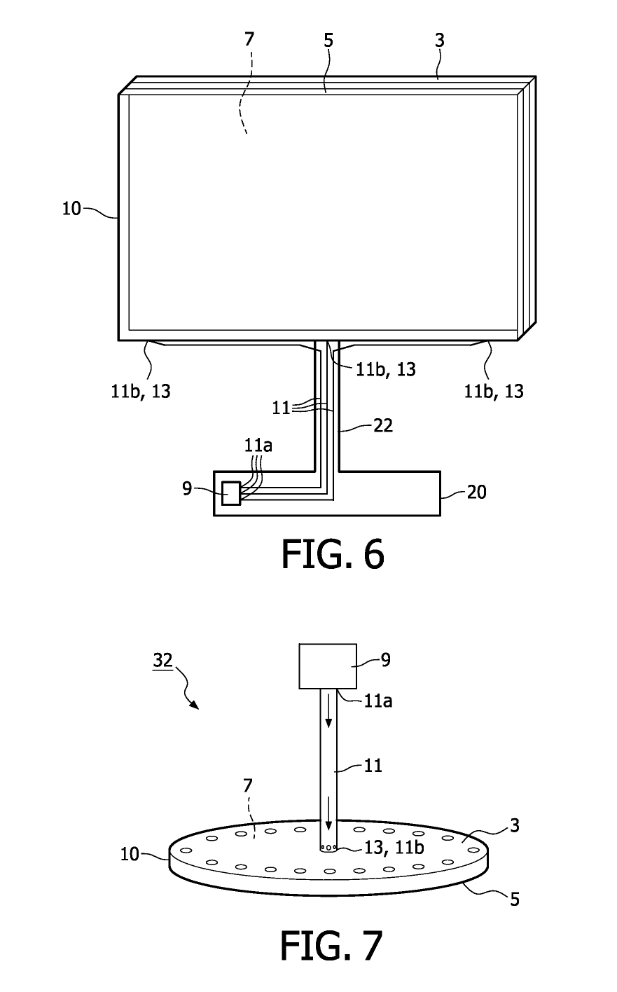

In FIG. 6 a display apparatus 2 is disclosed, which mainly distinguishes itself from the apparatus disclosed in FIGS. 4A and 4B by the provision of a set top box 20 in which a synthetic jet generator 9 is accommodated. Moreover the apparatus 2 has a thin enclosure 10 defining a gas-like space 7 and being is provided with three apertures 13, located at different positions of its outline. Each aperture 13 is connected to an end 11b of a tube 11, wherein an other end 11a of each tube 11 is connected to the single synthetic jet generator 9. The three tubes 11 are at least partly accommodated in a stand 22. In this embodiment the synthetic jet generator 9 communicates with the gas-like space 7 via three tubes 11 and three apertures 13. Alternatively, more generators and/or more or less tubes, pipes and the like, may be applied. For the rest reference is made to the described display apparatus of FIGS. 4A and 4B.

In FIG. 7 a luminary 32 is disclosed, provided with a configuration of two walls constituted by a LED panel 3 and a glass plate 5 facing the panel 3 and confining a substantially closed gap-like space 7 extending between the panel 3 and the plate 5 and containing air. The luminary 32 is further provided with a synthetic jet generator 9, e.g. formed by a loudspeaker, for generating a synthetic jet. The generator 9 is fluidically coupled to the gas-like space 7 by means of a channel, in this example a small round tube 11. The panel 3 and the plate 5 together form an enclosure 10 having the gap-like space 7 and being provided with an aperture 13 to which one end 11b of the tube 11 is connected. The other end 11a of the tube 11 is connected to the synthetic jet generator 9. By this construction the synthetic jet generator is able to communicate with the gas-like space 7 via the tube 11 and the aperture 13 in order to obtain cooling effects, in a way as already described in the foregoing.

While the invention has been illustrated and described in detail in the drawings and foregoing description, illustration and description are to be considered illustrative or exemplary and not restrictive. The invention is not limited to the disclosed embodiments. In this context it is emphasized that the invention is not restricted to large-area or wide-screen or flat screen devices or apparatus. The benefits of the invention are also obtainable in smaller devices, such as screen apparatus having conventional shapes and/or dimensions. All components of the devices and apparatus according to the invention can be made by applying processes and materials known per se. Other variations to the disclosed embodiments can be understood and effected by the skilled person in practicing the claimed invention, from a study of the drawings, the description and the claims. In the Claims and the description the word “comprising” does not exclude other elements, and the indefinite article “a” or “an” does not exclude a plurality. Any reference sign in the Claims should not be construed as limiting the scope.

1. A device (1) provided with
a configuration of two walls (3a; 5a) confining a substantially closed gap-like space (7) extending between said walls and containing a gaseous medium, and
a synthetic jet generator (9) for generating a gaseous synthetic jet, which generator is fluidically coupled to the gas-like space.

2. The device as claimed in claim 1, wherein a coupling channel (11) is provided for fluidically coupling the synthetic jet generator to the gap-like space.

3. The device as claimed in claim 1, wherein the two walls form a sealed enclosure (10) defining the gap-like space and provided with an aperture (13), via which aperture the synthetic jet generator communicates with the gas-like space.

4. The device as claimed in claim 1, wherein at least one of the walls is formed by a panel structure (3).

5. The device as claimed in claim 1, wherein one of the walls is formed by a display panel structure and the other wall is formed by a transparent or translucent plate structure (5).

6. The device as claimed in claim 5, wherein the display panel structure comprises a panel out of the group constituted by a liquid crystal panel, a plasma panel, an organic light-emitting diode panel and a light-emitting diode panel.

7. The device as claimed in claim 5, wherein the transparent or translucent plate structure comprises a glass plate.

8. The device as claimed in claim 1, wherein the gaseous medium is air and the gaseous synthetic jet is an air jet.

9. The device as claimed in claim 1, wherein the synthetic jet generator is configured for generating pulses at a frequency being in a range between 0 and 51 Hz.

10. The device as claimed in claim 1, wherein the synthetic jet generator is comprises a loudspeaker.

11. A display apparatus (2) provided with the device as claimed in claim 1.

12. A luminary (32) provided with the device as claimed in claim 1.
